(19) United States
(12) Patent Application Publication
(10) Pub. No.: US 2010/0009290 A1
(43) Pub. Date: Jan. 14, 2010

(54) Photosensitive Polybenzoxazines and Methods of Making the Same

(75) Inventors: Kazuhiro Yamanaka, Tokyo (JP); Clifford Henderson, Douglasville, GA (US); Michael Romeo, Fort Worth, TX (US); Kazuhiko Maeda, Tokyo (JP)

Correspondence Address: CANTOR COLBURN, LLP, 20 Church Street, 22nd Floor, Hartford, CT, 06103, US

(73) Assignees: CENTRAL GLASS CO., LTD., Yamaguchi (JP); GEORGIA TECH RESEARCH CORPORATION, Office of Technology Licensing, Atlanta, GA (US)

(21) Appl. No.: 12/517,511

(22) PCT Filed: Dec. 3, 2006
(86) PCT No.: PCT/US06/61540

§ 371 Date: Jun. 3, 2009

(51) Int. Cl. G03F 7/00; C08G 69/00; C08F 2/46; C08G 59/00; C08F 26/00

(52) U.S. Cl. 430/280.1; 522/174; 430/270.1; 430/283.1; 522/170; 522/167; 522/47; 522/65; 522/63; 522/67; 522/57; 522/59

(57) ABSTRACT

Photosensitive polybenzoxazine compositions include a photosensitive additive such as an o-diazoquinone and a polymer comprising a repeating unit represented by the following formula (I) wherein R¹ comprises an aliphatic group, an alicyclic group, an aromatic group, a heterocyclic group, or combinations thereof, R² comprises an aliphatic group, an alicyclic group, an aromatic group, a heterocyclic group, or combinations thereof, R⁴ comprises a hydrophilic group, a hydrophilic group protected by an acid-cleavable group, a hydrophilic group protected by a base-cleavable group, a cross-linkable group, or combinations thereof, and i represents an integer of 1 or more. The photosensitive compositions may be formed by combining a precursor polymer with a photosensitive additive and a solvent, patterning the precursor polymer, and heating the precursor polymer at a thermal processing temperature in a range of from about 180° C. to about 300° C. to convert the precursor polymer into the final polymer.

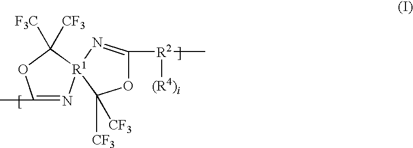

### FIELD OF THE INVENTION

The present invention generally relates to photosensitive compositions, and more particularly to photosensitive polybenzoxazines made by processing precursor polymers at relatively low temperatures, wherein the polybenzoxazines exhibit certain desirable properties such as relatively low dielectric constants.

### BACKGROUND OF THE INVENTION

Heterocyclic polymeric materials, e.g., polyimides (PIs), polybenzoxazoles (PBOs), polybenzimidazoles, and polybenzthiazoles, are widely known as high performance materials in the microelectronics field. Such materials exhibit excellent thermal stability and chemical resistance. Further, they typically exhibit relatively low dielectric constants. In addition, photosensitive versions of these materials typically possess the ability to change their solubility in response to being exposed to appropriate radiation such as ultraviolet light. Further, they are photodefinable which refers to their ability to be directly patterned using photolithography. Lithography is the process by which small structures or features, typically the size of a few microns, are patterned in a layer of material formed upon a substrate. More specifically, photolithography is the process by which most integrated circuits are patterned today and involves transferring an optical image from a patterned mask plate known as a “photomask” or “reticle” to the photosensitive material. Accordingly, such polymeric materials have commonly been used as insulation layers and passivation layers for very-large-scale-integration (VLSI) and multichip modules (MCM).

Significant research on conventional photosensitive PIs and PBOs has been reported that indicates both polymers generally may be prepared by applying a thermal cyclization process to corresponding precursor polymers, e.g., a polyamic-acid and a poly o-hydroxy amide. This thermal cyclization process refers to the conversion of a precursor polymer to its corresponding ring closed form (e.g. a polyamic-acid is converted to a polyimide or a poly o-hydroxy amide is converted to a polybenzoxazole). Due to the good solubility of the precursor polymers in various solvents, these polymers may be dissolved in suitable solvents and deposited as thin films on microelectronic substrates using simple methods such as spin casting before being thermally converted. The good solubility of the precursor polymers has also allowed such PIs and PBOs to be applied to fields other than microelectronics such as the aerospace field.

Unfortunately, the thermal cyclization process described above is typically performed at relatively high temperatures of greater than about 320° C. This high temperature treatment may lead to thermal stresses in an integrated circuit containing one or more PI or PBO layers, resulting in problems such as warpage of the integrated circuit. Further, it may also result in discoloration of PI or PBO films or other materials used in combination therewith, such as color filters, in a liquid crystal display manufacturing process. It is therefore desirable to develop photosensitive polymeric materials that can be prepared from a polymeric precursor without being subjected to high temperatures. It is further desirable that the photosensitive polymeric materials exhibit certain properties useful in their various applications such as a low dielectric constant and good solubility in various solvents.

### SUMMARY OF THE INVENTION

According to various embodiments, photosensitive compositions include a photosensitive additive and a polymer comprising a repeating unit represented by the following formula:

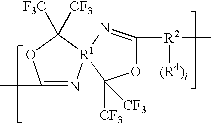

wherein R¹ comprises an aliphatic group, an alicyclic group, an aromatic group, a heterocyclic group, or combinations thereof, R² comprises an aliphatic group, an alicyclic group, an aromatic group, a heterocyclic group, or combinations thereof, R⁴ comprises a hydrophilic group, a hydrophilic group protected by an acid-cleavable group, a hydrophilic group protected by a base-cleavable group, a hydrophilic group protected by a cross-linkable group, or combinations thereof, and i represents an integer of 1 or more. Examples of suitable polymers are described in International Patent Application Nos. WO/2006/043501 and WO/2006/041115, which are incorporated by reference herein in their entirety. These exemplary polymers exhibit very useful properties, including water repellency, oil repellency, low water absorption, heat resistance, corrosion resistance, high transparency, low refractive index, and low dielectric constants. Further, they may be formed via a low thermal cyclization temperature of less than 300° C.

The aforementioned photosensitive additive may comprise, for example, a photosensitive dissolution inhibitor, a photoacid generator, a photobase generator, a photo-free radical generator, or combinations thereof. Such photosensitive compositions exhibit desirable properties such as relatively low dielectric constants and low water absorption.

In more embodiments, methods of forming the foregoing photosensitive compositions include combining a precursor polymer with a photosensitive additive and a suitable solvent. The resulting photosensitive precursor polymer may then be patterned using lithography, followed by heating the precursor polymer at a thermal processing temperature in a range of from about 180° C. to about 300° C. to convert the precursor polymer into the final polymer. The use of such a low thermal processing temperature ensures that the photosensitive compositions do not undergo heat damage during their preparation. Further, the photosensitive compositions may be used for various applications without being concerned that the thermal processing temperature could cause problems for those applications. For example, the photosensitive compositions may be employed as dielectric films upon layers of an integrated circuit without subjecting the integrated circuit components to a high thermal processing temperature that could compromise the integrity of the circuit.

The aforementioned photosensitive precursor polymers may include a photosensitive additive and a repeating unit represented by the following formula:

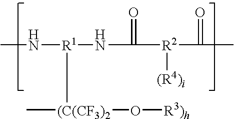

wherein R¹ comprises an aliphatic group, an alicyclic group, an aromatic group, a heterocyclic group, or combinations thereof, R² comprises an aliphatic group, an alicyclic group, an aromatic group, a heterocyclic group, or combinations thereof, R³ represents hydrogen or an organic group comprising a hydrophilic group, an acid-cleavable group, a base-cleavable group, a cross-linkable group, or combinations thereof, R⁴ comprises a hydrophilic group, a hydrophilic group protected by an acid-cleavable group, a hydrophilic group protected by a base-cleavable group, a hydrophilic group protected by a cross-linkable group, or combinations thereof, h represents an integer of 1 or more, and i represents an integer of 0, 1, or more. Such photosensitive precursor polymers are soluble in various organic solutions and photolithography developing solutions. Further, these precursor polymers may serve as either positive or negative tone photodefinable films.

### BRIEF DESCRIPTION OF THE DRAWINGS

FIG. 1 is an optical micrograph of photolithography patterns obtained in a trihydroxybenzophenone-loaded polybenzoxazine film.

### DETAILED DESCRIPTION OF THE PREFERRED EMBODIMENTS

In accordance with various embodiments, photosensitive compositions include:

(a) a polymer comprising a repeating unit generally represented by the following formula:

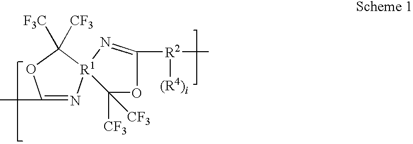

wherein R¹ comprises an aliphatic group, an alicyclic group, an aromatic group, a heterocyclic group, or combinations thereof, R² comprises an aliphatic group, an alicyclic group, an aromatic group, a heterocyclic group, or combinations thereof, R⁴ comprises a hydrophilic group, a hydrophilic group protected by an acid-cleavable group, a hydrophilic group protected by a base-cleavable group, a hydrophilic group protected by a cross-linkable group, or combinations thereof, and i represents an integer of 1 or more; and
(b) a photosensitive additive, which differentiates the dissolution rates in a developing solution of areas of the photosensitive compositions exposed and unexposed to actinic light irradiation to allow the formation of a relief pattern. The above polymer is hereafter referred to as the “PBOX polymer” where “PBOX” stands for polybenzoxazine.

In various embodiments of the PBOX polymer, R⁴ in scheme 1 is represented by one of the following formulas:

—OR¹⁰

—COOR¹⁰

—SO₃R¹⁰

—NR¹⁰—SO₂CF₃

wherein R¹⁰ is represented by hydrogen (H) or an organic group comprising an acid-cleavable group, a base-cleavable group, a cross-linkable group, or combinations thereof. For example, R¹⁰ may be represented by one of the following formulas:

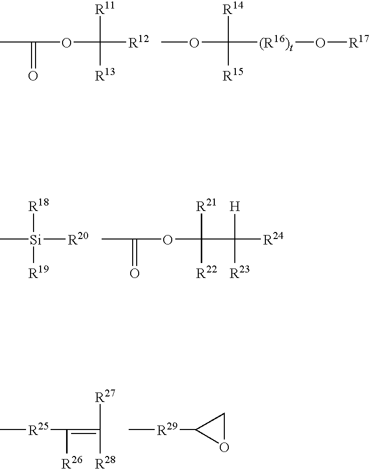

wherein R¹¹, R¹², and R¹³ each represents hydrogen or an organic group comprising from 1 to 40 carbon atoms, R¹⁴ and R¹⁵ each represents hydrogen or an organic group comprising from 1 to 40 carbon atoms, R¹⁶ and R¹⁷ each represents an organic group comprising from 1 to 40 carbon atoms, t represents an integer of 0 or 1, wherein R¹⁸, R¹⁹, and R²⁰ each represents an organic group comprising from 1 to 40 carbon atoms, R²¹, R²², R²³, and R²⁴ each represents hydrogen or an organic group comprising from 1 to 40 carbon atoms, R²⁵ represents an organic group comprising from 1 to 40 carbon atoms, R²⁶, R²⁷, and R²⁸ each represents hydrogen or an organic group comprising from 1 to 40 carbon atoms, and R²⁹ represents an organic group comprising from 1 to 40 carbon atoms.

In more embodiments of the PBOX polymer, R¹ in scheme 1 is represented by the following formula:

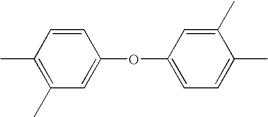

Also, R²—(R⁴)ᵢ is represented by the following formula:

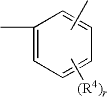

wherein R⁴ is represented by the following formula:

—OR¹⁰

wherein R¹⁰ represents hydrogen or an organic group comprising an acid-cleavable group, a base-cleavable group, a cross-linkable group, or combinations thereof. Additionally r above represents an integer of 1, 2, 3, or 4.

In yet more embodiments of the PBOX polymer, R¹ in scheme 1 is represented by the following formula:

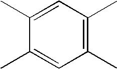

Also, R²—(R⁴)ᵢ is represented by the following formula:

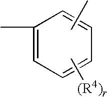

wherein R⁴ is represented by the following formula:

—OR¹⁰

wherein R¹⁰ represents hydrogen or an organic group comprising an acid-cleavable group, a base-cleavable group, a cross-linkable group, or combinations thereof. Additionally, r above represents an integer of 1, 2, 3, or 4.

In yet more embodiments of the PBOX polymer, R²—(R⁴)ᵢ in scheme 1 is represented by one of the following formulas:

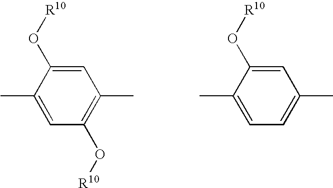

wherein R¹⁰ represents hydrogen or an organic group represented by one of the following formulas:

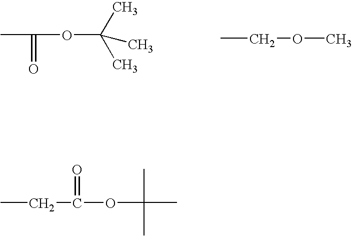

As mentioned above, the photosensitive compositions may include one or more photosensitive additives. The photosensitive additive serves to differentiate the alkali solubility of the exposed region of the PBOX polymer from that of the non-exposed region. Distinct photosensitive additives have different absorption wavelengths. Therefore, by using distinct actinic lights corresponding to the different photosensitive additives, a pattern can be formed in the photosensitive composition by distinct stages.

In various embodiments, the photosensitive additive may be of the type that suppresses the alkali solubility of the PBOX polymer in the absence of actinic light. However, when actinic light is irradiated upon the PBOX polymer in the presence of this type of photosensitive additive, an alkali soluble moiety is formed. Thus, the exposed region becomes soluble in an alkali solution, whereas the non-exposed region is still insoluble in the alkali solution. Therefore, the combination of the PBOX polymer and this type of photosensitive additive forms a positive tone photodefinable film. Examples of such photosensitive additives include but are not limited to diazonium salts, o-diazoquinones (o-quinone diazides) such as o-diazonaphthoquinones (DNQ), diazoquinone sulphonamides, diazoquinone sulphonic acid esters, and diazoquinone sulphonates, and combinations thereof.

The o-diazoquinone compound may be obtained, for example, by a condensation reaction of an o-quinonediazide sulphonyl chloride with a polyhydroxy compound, a polyamine compound, or a polyhydroxy polyamine compound. Examples of o-quinonediazide sulphonyl chloride compounds include but are not limited to 1,2-benzoquinone-2-azido-4-sulphonyl chloride, 1,2-naphthoquinone-2-diazido-5-sulphonyl chloride, 1,2-naphthoquinone-2-diazido-6-sulphonyl chloride, 1,2-naphthoquinone-2-diazido-4-sulphonyl chloride, and combinations thereof. Examples of polyhydroxy compounds include but are not limited to hydroquinone, resorcinol, pyrogallol, bisphenol A, bis(4-hydroxyphenyl)methane, 2,2-bis(4-hydroxyphenyl)hexafluoropropane, 2,3,4-trihydroxybenzophenone, 2,3,4-trihydroxy diphenyl methane, 2,3,4,4′-tetrahydroxy diphenyl methane 2,3,4,4′-tetrahydroxybenzophenone, 2,2′,4,4′-tetrahydroxybenzophenone, tris(4-hydroxyphenyl)methane, 1,1,1-tris(4-hydroxyphenyl)ethane, 1-[1-(4-hydroxyphenyl)isopropyl]-4-[1,1-bis(4-hydroxyphenyl)ethyl]benzene, 1-naphthol, 2-naphthol, methyl gallate, ethyl gallate, and combinations thereof. Examples of polyamine compounds include but are not limited to 1,4-phenylenediamine, 1,3-phenylenediamine, 4,4′-diaminodiphenyl ether, 4,4′-diaminodiphenylmethane, 4,4′-diaminodiphenylsulphone, 4,4′-diaminodiphenylsulphide, and combinations thereof. Examples of polyhydroxy polyamine compounds include but are not limited to 2,2-bis(3-amino-4-hydroxyphenyl)hexafluoropropane, 3,3-dihydroxybenzidine, and combinations thereof.

Specific examples of o-diazoquinone compounds include but are not limited to 1,2-benzoquinone-2-azido-4-sulphonate ester or sulphonamide, 1,2-napththoquinone-2-diazido-5-sulphonate ester or sulphonamide, 1,2-naphthoquinone-2-diazido-4-sulphonate ester or sulphonamide, and combinations thereof. The amount of o-diazoquinone included in the photosensitive composition may be in the range of from about 0.01% to about 40%, alternatively in the range of from about 5% to about 30%, or alternatively in the range of from about 15% to about 25%, these percentages being by weight of the total solids.

In more embodiments, the photosensitive additive may be one or more photoacid generators. A photoacid generator generates an acid when it is exposed to actinic light. Examples of suitable photoacid generators include but are not limited to onium salts, sulfonate esters, disulfonyldiazomethanes, nitrobenzyl esters, vicinal halides, halogenated isocyanates, triazine halides, disulphones, and combinations thereof. The combination of the PBOX precursor polymer and the photoacid generator forms a positive tone photodefinable film. The amount of photoacid generator included in the photosensitive composition may be in the range of from about 0.01% to about 20%, alternatively in the range of from about 0.5% to about 10%, or alternatively in the range of from about 1% to about 7%, these percentages being by weight of the total solids.

In yet more embodiments, the photosensitive additive may be one or more photobase generators. A photobase generator generates a base when it is exposed to actinic light. The photobase generator may be, for example, a cobalt amine complex as represented by Co(III)(RNH₂)₅X²⁺, wherein R represents hydrogen or an alkyl group comprising 1 or more carbon atoms and X represents Br⁻ or Cl⁻. Other examples of suitable photobase generators include but are not limited to oxime esters, carbamic acids, nitrobenzyl sulfonamides, quaternary ammonium salts, and combinations thereof. The combination of the PBOX precursor polymer and the photobase generator forms a positive tone photodefinable film. The amount of photobase generator included in the photosensitive composition may be in the range of from about 0.01% to about 20%, alternatively in the range of from about 0.5% to about 10%, or alternatively in the range of from about 1% to about 7%, these percentages being by weight of the total solids.

In still more embodiments, the photosensitive additive may be one or more photo-free radical generators. A photo-free radical generator generates a radical when it is exposed to actinic light. Examples of suitable photo-free radical generators include but are not limited to benzoin ethers, benzyl derivatives, trichlorotriazines, phosphine oxides, and combinations thereof. The amount of photo-free radical generator included in the photosensitive composition may be in the range of from about 0.01% to about 20%, alternatively in the range of from about 0.5% to about 10%, or alternatively in the range of from about 1% to about 7%, these percentages being by weight of the total solids.

The photosensitive compositions may optionally include one or more photosensitizers. In particular, if the photosensitive composition as prepared is transparent to the wavelength of the actinic light, a photosensitizer may be useful. The photosensitizer is desirably capable of receiving the energy of the actinic light and transferring it to the photosensitive additive. Thus, the particular photosensitive additive present in the photosensitive composition influences the choice of the photosensitizer. Examples of suitable photosensitizers include but are not limited to aromatic compounds such as naphthalenes, anthracenes, and pyrenes, carbazole derivatives, aromatic carbonyl compounds, benzophenone derivatives, thioxanthone derivatives, coumarin derivatives, and combinations thereof. Specific examples of suitable photosensitizers include but are not limited to 1-methylnaphthalene, 2-methylnaphthalene, 1-fluoronaphthalene, 1-chloronaphthalene, 2-chloronaphthalene, 1-bromonaphthalene, 2-bromonaphthalene, 1-iodinenaphthalene, 2-iodinenaphthalene, 1-naphthol, 2-naphthol, 1-methoxynaphthalene, 2-methoxynaphthalene, 1,4-dicyanonaphthalene, anthracene, 1,2-benzanthracene, 9,10-dichloroanthracene, 9,10-dibromoanthracene, 9,10-diphenylanthracene, 9-cyanoanthracene, 9,10-dicyanoanthracene, 2,6,9,10-tetracyanoanthracene, carbazole, 9-methylcarbazole, 9 phenylcarbazole, 9-propyl-9H-carbazole, 9-vinylcarbazole, 9H-carbazole-9-ethanol, 9-methyl-3-nitro-9H-carbazole, 9-methyl-3,6-dinitro-9H-carbazole, 9-carbazole methanol, 9-carbazole propionic acid, 9-decyl-3,6-dinitro-9H-carbazole, 9-ethyl-3,6-dinitro-9H-carbazole, 9-ethyl-3-nitrocarbazole, 9-ethylcarbazole, 9-isopropylcarbazole, 9-(ethoxycarbonylmethyl) carbazole, 9-(morpholinomethyl)carbazole, 9-acetylcarbazole, 9-arylcarbazole, 9-benzyl-9H-carbazole, 9-carbazole acetic acid, 9-(2-nitrophenyl) carbazole, 9-(4-methoxyphenyl)carbazole, 9-(1-ethoxy-2-methyl-propyl)-9H-carbazole, 3-nitrocarbazole, 4-hydroxycarbazole, 3,6-dinitro-9H-carbazole, 3,6-diphenyl-9H-carbazole, 2-hydroxycarbazole, 3,6-diacetyl-9-ethylcarbazole, benzophenone, 4-phenylbenzophenone, 4,4′-bis(dimethoxy)benzophenone, 4,4′-bis(dimethylamino) benzophenone, 4,4′-bis(diethylamino) benzophenone, 2-benzoylbenzoic acid methyl ester, 2-methylbenzophenone, 3-methylbenzophenone, 4-methylbenzophenone, 3,3′-dimethyl-4-methoxybenzophenone, 2,4,6-trimethylbenzophenone, [4-(4-methylphenylthio) phenyl]-phenylmethanone, xanthone, thioxanthone, 2-chlorothioxanthone, 4-chloro thioxanthone, 2-isopropyl thioxanthone, 4-isopropyl thioxanthone, 2,4-dimethyl thioxanthone, 2,4-diethyl thioxanthone, 1-chloro-4-propoxy thioxanthone, and combinations thereof. The amount of photosensitizer included in the photosensitive composition may be in the range of from about 0.01% to about 20%, alternatively in the range of from about 0.5% to about 10%, or alternatively in the range of from about 1% to about 7%, these percentages being by weight of the total solids.

Optionally, the photosensitive compositions also may include one or more thermal acid generators. A thermal acid generator generates an acid when it is exposed to heat but not when it is exposed to light. After the development of a relief pattern in the photosensitive composition, it is usually heated, causing the thermal acid generator to generate acid which in turn assists in the cleavage of the acid-cleavable group. Examples of suitable thermal acid generators include but are not limited to halogenoid nitrogen-containing compounds that generate a halogen radical when exposed to heat, sulfonate esters such as nitrobenzyl sulfonates, and combinations thereof. The amount of thermal acid generator included in the photosensitive composition may be in the range of from about 0.01% to about 20%, alternatively in the range of from about 0.1% to about 10%, or alternatively in the range of from about 1% to about 7%, these percentages being by weight of the total solids.

In addition, one or more cross-linkers optionally may be added to the photosensitive compositions. The cross-linker causes a cross-linking reaction such that regions of the photosensitive composition exposed to actinic light become insoluble in an alkali solution. Therefore, the combination of the PBOX polymer, a cross-linker, and a photoacid generator or a photobase generator forms a negative tone photodefinable film. When the acid-cleavable group, base-cleavable group, thermal cleavable group and/or hydrophilic group remain after forming a relief pattern in the photosensitive composition, the cross-linker may react with these groups. As a result of this reaction by the cross-linker, certain properties, e.g., the tensile strength, of the relief pattern may be modified. For example, if a hydrophilic group such as a hydroxyl group or carboxyl group is generated at the portion where R³ is cleaved off, the cross-linker can react with the generated hydrophilic group. It is to be understood that as used herein, the term “cross-linker” refers to a compound that is different from a cross-linkable group included in the PBOX polymer. The cross-linker may include compounds which have two or more epoxy groups, vinyl ether groups, acrylate groups, methacrylate groups, methylol groups, alkoxymethyl groups, or combinations thereof. Examples of suitable cross-linkers include but are not limited to bisphenol A epoxy resins, bisphenol F epoxy resins, bisphenol AD epoxy resins, cresol novolac epoxy resins, phenol novolac epoxy resins, glycidyl amine epoxy resins, polysulfide epoxy resins, dimethylol ureas, alkoxy methyl melamines, and combinations thereof. The amount of cross-linker included in the photosensitive composition may be in the range of from about 0.01% to about 40%, alternatively in the range of from about 0.1% to about 20%, or alternatively in the range of from about 1% to about 10%, these percentages being by weight of the total solids.

One or more solvents also may be included in the photosensitive compositions to dissolve or homogenously disperse the components therein. Examples of suitable solvents include but are not limited to organic solvents such as amides, ether esters, ketones, esters, glycol ethers, hydrocarbons, aromatic hydrocarbons, fluorinated solvents, carbonates, and combinations thereof. More specific examples of organic solvents include but are not limited to N,N-dimethyl formamide (DMF), gamma(γ)-butyrolactone (GBL), propylene glycol methyl ether (PGME), propylene glycol methyl ether acetate (PGMEA), tetrahydrofuran (THF), 1-methyl-2-pyrrolidinone (NMP), N,N-dimethylacetamide (DMAC), cyclohexanone, and combinations thereof.

The photosensitive compositions may be prepared by first synthesizing a PBOX precursor polymer via polycondensation of a mixture of a substituted organic diamine compound, e.g., a hexafluoroisopropanol-substituted orthodiamine (HFA-ODA), and an acyl halide compound, e.g., a dicarboxylic acid chloride compound. The PBOX precursor polymer may then be combined with a photosensitive additive and a suitable solvent as described above to form a photosensitive PBOX precursor composition. Subsequently, a relief pattern may be formed in the PBOX precursor composition using photolithography. In particular, photolithography entails first coating a layer of an ensuing integrated circuit with the photosensitive precursor composition via spin coating, spray coating, or roller coating. The layer of the integrated circuit may comprise, for example, a conductive or dielectric layer residing upon a semiconductor substrate such as a silicon substrate or ceramic or gallium arsenide substrate. Generally, the PBOX precursor composition is applied such that after being dried it has a thickness of from about 0.1 μm (micrometer) to about 300 μm. The drying process generally may be carried out at a temperature of from about 50° C. to about 150° C. for a period of 1 minute to several hours.

The photolithography steps further include placing a reticle with a desired pattern adjacent to the PBOX precursor composition and passing actinic light through transparent regions of the reticle to the photosensitive composition. Other regions of the reticle block the light, thereby preventing it from reaching underlying regions of the PBOX precursor composition. The reticle may be aligned to underlying structures of the integrated circuit before exposing the PBOX precursor composition to the light. Alternatively, the use of a laser beam via a direct write process may be employed to eliminate the process of applying the reticle. By exposing the PBOX precursor composition to light, the alkali solubility of the exposed portion becomes differentiated from the non-exposed portion. Generally, an actinic light which has a wavelength sensitive to the photosensitive additive may be used. Examples of suitable actinic light radiation include but are not limited to ultraviolet light, far ultraviolet light, infrared light, an electron beam, X-rays, and the like. For example, 248 nm (KrF line), 308 nm, 365 nm α-line), 405 nm (H-line), 436 nm (G-line), and 488 nm radiation may be used. One desirable property of the PBOX precursor composition is that it exhibits an absorbance in the range of from about 0.01 to about 0.5 μm⁻¹ for I-line radiation.

Subsequently, the PBOX precursor composition may be subjected to a development process. As mentioned previously, it may serve as either a positive or a negative tone photodefinable material because it becomes more or less soluble in a developing solution (“developer”) when exposed to actinic light. In the case of a positive tone material, the exposed regions may be removed by dissolving them in a developer. In the case of a negative tone material, the non-exposed regions may be removed by dissolving them in a developer. In one embodiment, the developer may be an alkaline aqueous solution, which includes a base component such as tetramethylammonium hydroxide (TMAH), diethanolamine, diethylaminoethanol, sodium hydroxide, potassium hydroxide, sodium carbonate, potassium carbonate, triethylamine, diethylamine, methylamine, dimethylamine, dimethylaminoethyl acetate, dimethylaminoethanol, cyclohexylamine, ethylenediamine, hexamethylenediamine, and combinations thereof. The molarity of the alkaline aqueous solution may be, for example, in the range of from about 0.5% to about 6%. In an alternative embodiment, the developer may be an organic solution. Examples of suitable organic solutions include but are not limited to the following: polar solvents such as N-methyl-2-pyrrolidone, N,N-dimethylformamide, N,N-dimethylacetamide, dimethylsulphoxide, γ-butyrolactone, and dimethylacrylamide; alcohols such as methanol, ethanol, and isopropanol; esters such as ethyl lactate and propylene glycol monomethyl ether acetate; ketones such as cyclopentanone, cyclohexanone, isobutyl ketone, and methyl isobutyl ketone; and combinations thereof. As a result of the development process, a relief pattern is formed in the PBOX precursor composition. Following development, the PBOX precursor composition may be rinsed with water.

The PBOX precursor residing in the patterned precursor composition may be further converted into the PBOX polymer by heating the precursor composition at a thermal processing temperature in the range of from about 180° C. to about 300° C., preferably in the range of from about 200° C. to about 260° C. This heating step may be performed for a period of from about 10 minutes to about 2 hours, preferably in the range of from about 15 minutes to about 1 hour. In this manner, high resolution structures that comprise the PBOX polymer may be produced using relatively low temperatures. As described previously, the use of such low thermal processing temperatures to form the PBOX polymer avoids subjecting the polymer and surrounding materials, such as layers of an integrated circuit, to damaging thermal stresses.

The PBOX precursor polymer mentioned above generally may be represented by the following formula:

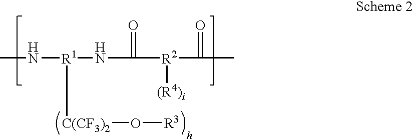

wherein R¹ comprises an aliphatic group, an alicyclic group, an aromatic group, a heterocyclic group, or combinations thereof, R² comprises an aliphatic group, an alicyclic group, an aromatic group, a heterocyclic group, or combinations thereof, R³ represents hydrogen or an organic group comprising a hydrophilic group, an acid-cleavable group, a base-cleavable group, a cross-linkable group, or combinations thereof, R⁴ comprises a hydrophilic group, a hydrophilic group protected by an acid-cleavable group, a hydrophilic group protected by a base-cleavable group, a hydrophilic group protected by a cross-linkable group, or combinations thereof, h represents an integer of 1 or more, and i represents an integer of 0, 1, or more.

In various embodiments of the PBOX precursor polymer, R³ in scheme 2 is represented by the following formula:

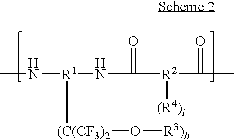

wherein R⁸ represents an organic group comprising from 1 to 40 carbon atoms, R⁹ comprises a hydrophilic group, a hydrophilic group protected by an acid-cleavable group, a hydrophilic group protected by a base-cleavable group, a hydrophilic group protected by a cross-linkable group, or combinations thereof, m represents an integer of 0 or 1, and n represents an integer of 1 or more.

In one embodiment, R⁹ above is represented by one of the following formulas:

—COOR¹⁰

—SO₃R¹⁰

—OR¹⁰

—NR¹⁰—SO₂CF₃

wherein R¹⁰ represents hydrogen or an organic group comprising an acid-cleavable group, a base-cleavable group, a cross-linkable group, or combinations thereof.

In one embodiment, R¹⁰ above is represented by one of the following formulas:

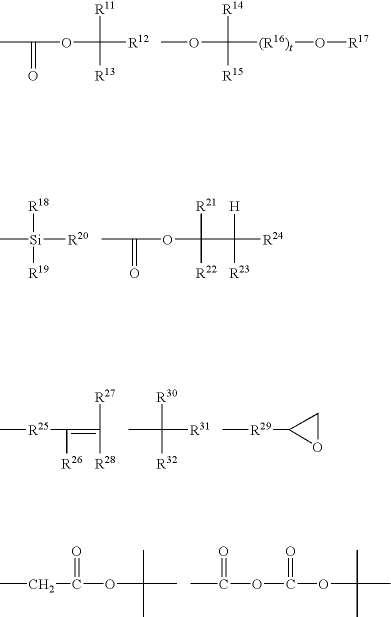

wherein R¹¹, R¹², and R¹³ each represents hydrogen or an organic group comprising from 1 to 40 carbon atoms, R¹⁴ and R¹⁵ each represents hydrogen or an organic group comprising from 1 to 40 carbon atoms, R¹⁶ and R¹⁷ each represents an organic group comprising from 1 to 40 carbon atoms, t represents an integer of 0 or 1, R¹⁸, R¹⁹, and R²⁰ each represents an organic group comprising from 1 to 40 carbon atoms, R²¹, R²², R²³, and R²⁴ each represents hydrogen or an organic group comprising from 1 to 40 carbon atoms, R²⁵ represents an organic group comprising from 1 to 40 carbon atoms, R²⁶, R²⁷, and R²⁸ each represents hydrogen or an organic group comprising from 1 to 40 carbon atoms, R²⁹ represents an organic group comprising from 1 to 40 carbon atoms, and R³⁰, R³¹, and R³² each represents hydrogen or an organic group comprising from 1 to 40 carbon atoms.

In additional embodiments of the PBOX precursor polymer, R⁴ in scheme 2 is represented by one of the following formulas:

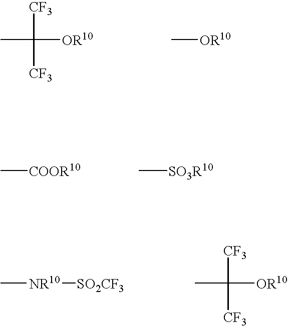

wherein R¹⁰ represents hydrogen or an organic group comprising an acid-cleavable group, a base-cleavable group, a cross-linkable group, or combinations thereof.

In more embodiments of the PBOX precursor polymer, R¹—(C(CF₃)₂—O—R³)ₕ in scheme 2 is represented by the following formula:

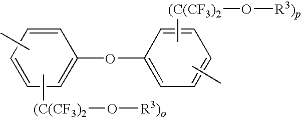

Also, R²—(R⁴)ᵢ is represented by the following formula:

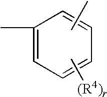

wherein R⁴ is represented by the following formula:

—OR¹⁰

wherein R¹⁰ represents hydrogen or an organic group comprising an acid-cleavable group, a base-cleavable group, a cross-linkable group, or combinations thereof. Additionally, each of p, o, and r above represents an integer of 0, 1, 2, 3, or 4 and p+o>0.

In yet more embodiments of the PBOX precursor polymer, R¹—(C(CF₃)₂—O—R³)ₕ in scheme 2 is represented by the following formula:

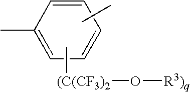

wherein q represents an integer of 1, 2, 3, or 4. Also, R²—(R⁴)ᵢ in scheme 2 is represented by the following formula:

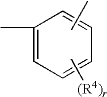

wherein r represents an integer of 0, 1, 2, 3, or 4 and R⁴ is represented by the following formula:

—OR¹⁰

wherein R¹⁰ represents hydrogen or an organic group comprising an acid-cleavable group, a base-cleavable group, a cross-linkable group, or combinations thereof.

In still more embodiments of the PBOX precursor polymer, R¹—(C(CF₃)₂—O—R³)ₕ in scheme 2 is represented by the following formula:

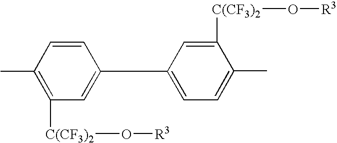

wherein R³ represents hydrogen or an organic group represented by one of the following formulas:

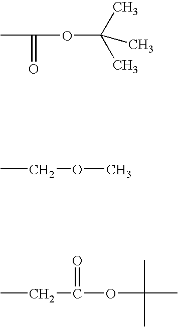

In further embodiments of the PBOX precursor polymer, R²—(R⁴)ᵢ in scheme 2 is represented by one of the following formulas:

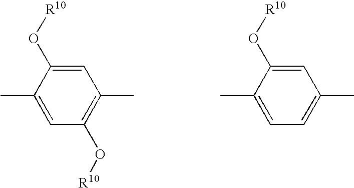

wherein R¹⁰ represents hydrogen or an organic group represented by one of the following formulas:

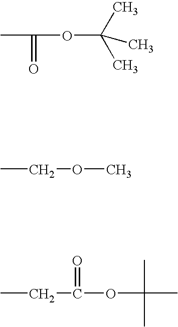

Examples of the synthesis of a specific PBOX precursor polymer that contains hexafluoroisopropanol groups and its corresponding PBOX polymer are given below as well as examples of suitable aromatic (Ar) substituents for the PBOX polymer:

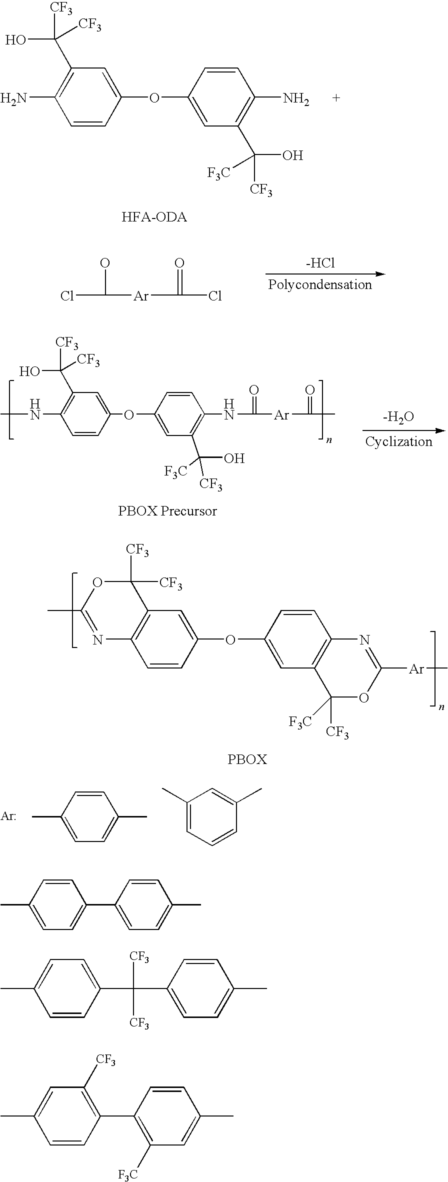

where n represents the degree of polymerization.

Additional examples of the conversion of specific PBOX precursor polymers to specific PBOX polymers containing hexafluoroisopropanol groups are provided below:

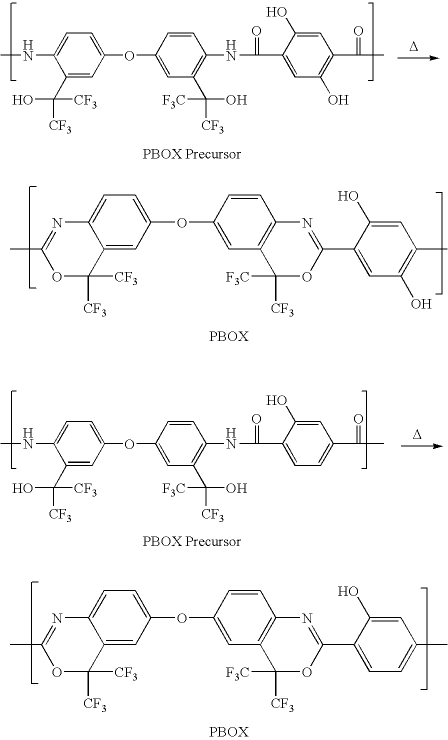

The PBOX polymer compositions described herein exhibit certain properties that make these compositions useful in various applications. For example, they exhibit relatively low dielectric constant values. In various embodiments, the dielectric constant values are in the range of from about 2.0 to about 3.0. In alternative embodiments, the dielectric constant values are in the range of from about 2.2 to about 2.6. The PBOX polymer compositions also exhibit relatively low water uptake. In various embodiments, the water absorption values are in the range of from about 0.01% to about 3% by weight of the polymer. In alternative embodiments, the water absorption values are in the range of from about 0.1% to about 1%. In addition, the PBOX polymer compositions may exhibit relatively high thermal stability, relatively high transparency, relatively high tensile strength, moderate glass transition temperatures, and moderate thermal expansion coefficients.

These properties allow the PBOX polymer compositions to serve as passivation and isolation layers in integrated circuits. The PBOX polymer compositions are photodefinable and thus may be patterned into structures of an integrated circuit using photolithography. Due to their ability to resist being removed by a chemical etchant, the PBOX polymer compositions also may serve as photoresist layers that protect underlying layers of integrated circuits from being removed. Moreover, they may serve as liquid crystal orienting films in liquid crystal display devices without the need to use high thermal processing temperatures that could discolor them or surrounding materials such as color filters. Other uses of the PBOX polymer compositions would be obvious to one skilled in the art.

### EXAMPLES

The invention having been generally described, the following examples are given as particular embodiments of the invention and to demonstrate the practice and advantages thereof. It is understood that the examples are given by way of illustration and are not intended to limit the specification or the claims to follow in any manner.

### Example 1

The following HFA-ODA starter compound was provided:

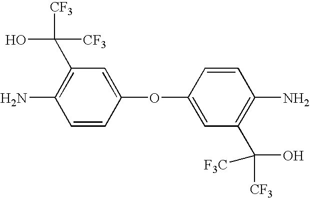

In a three-neck flask having a volume of 300 mL, 1.50 grams (g) of the HFA-ODA starter compound, 0.57 g of isophthaloyl dichloride (IPC), and 8 milliliters (mL) of N,N-dimethylacetamide (DMAc) were mixed for a period of 5 hours at room temperature in a nitrogen (N₂) atmosphere, allowing a polycondensation reaction to occur between the HFA-ODA starter compound and the IPC. The reaction liquid was combined with a mixture of methanol and water, resulting in the precipitation of the polymer. The polymer as precipitated was collected by filtration and then subjected to vacuum drying at a temperature of 50° C. The yield of the reaction was 96% by weight of the starter compound (1.80 g). Then the polymer was dissolved in 1-methyl-2-pyrrolidinone (NMP) such that its concentration in the solvent was 0.5 g/dL (deciliter). The intrinsic viscosity (ηᵢₙₕ) of the polymer solution at 25° C. as measured by an Ostwald viscometer was 0.26 dL/g. The results of NMR and infrared IR spectroscopy indicated that a PBOX precursor polymer comprising a repeating unit represented by the following formula had been formed:

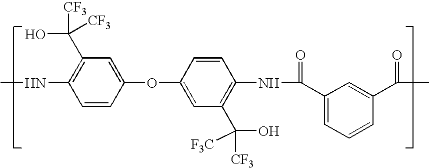

The above PBOX precursor polymer exhibited good solubility in a N,N-dimethylformamide (DMF) solvent and in a tetrahydrofuran (THF) solvent when mixed therein. The PBOX precursor polymer was subjected to a thermal processing temperature of 260° C. for 0.5 hour. The results of IR and thermal gravimetric analysis showed that the PBOX precursor polymer had undergone thermal conversion into a PBOX polymer comprising a repeating unit represented by the following formula:

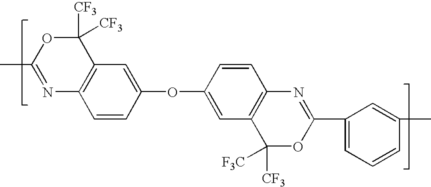

The thermal processing temperature required to form the PBOX polymer in this example is much lower than that required to form conventional polyimides and polybenzoxazoles. The water absorption of the above PBOX polymer was determined to be 0.4% by weight of the polymer.

The procedure described above was repeated using different starter compounds or mixtures of starter compounds (ratios given below are by molar ratios) like the HFA-ODA starter compound except that they contained different aryl groups as shown below in Table 1. The reaction yield by weight of the polymer, the intrinsic viscosity, and the solubility of the resulting PBOX precursor polymers are also shown in Table 1 below. Each of the PBOX precursor polymers was subjected to a thermal processing temperature of 260° C. for 0.5 hour. The results of IR and thermal gravimetric analysis showed that the PBOX precursor polymers had undergone thermal conversion into corresponding PBOX polymers.

TABLE 1

| PBOX | | | ηᵢₙₕ | Solubility¹ | | | |
|---|---|---|---|---|---|---|---|
| Precursor | | Yield | (dL/ | | γ- | | |
| Polymer | Ar | (%) | g) | DMF | GBL | PGMEA | THF |
| 1 | IPC | 96 | 0.60 | + | − | − | + |
| 2 | TPC | 94 | 0.26 | + | − | − | + |
| 3 | BPDC | 99 | 1.20 | + | − | − | + |
| 4 | 6FDC | 100 | 0.27 | + | + | + | + |
| 5 | 6FBDC | 95 | 0.68 | + | + | + | + |
| 6 | IPC/BPDC | 100 | 0.51 | + | − | − | + |
| | (50/50) | | | | | | |
| 7 | IPC/6FDC | 92 | 0.26 | + | + | + | + |
| | (50/50) | | | | | | |
| 8 | IPC/6FDC | 100 | 0.26 | + | | + | |
| | (75/25) | | | | | | |

¹(+): Soluble; (−): insoluble

The PBOX precursor polymers presented in Table 1 above may be represented by the following formula:

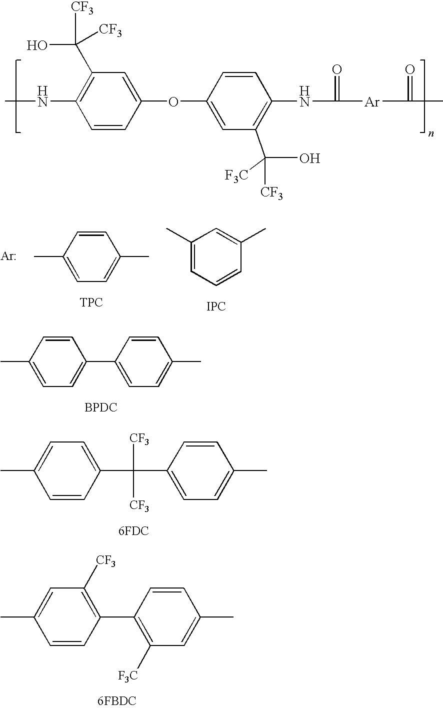

Using a UV-VIS spectrometer, the absorbance values of some of the PBOX precursor polymer films shown in Table 1 were measured with ultraviolet light having a wavelength of 365 nm. The results of those measurements are as follows: 0.04 μm⁻¹ for polymer 4; 0.12 μm⁻¹ for polymer 5; 0.06 μm⁻¹ for polymer 7; and 0.13 μm⁻¹ for polymer 8. Based on these absorbance values, the PBOX precursor polymers are sufficiently transparent to serve as photosensitive materials.

### Example 2

In a three-neck flask having a volume of 300 mL, 0.75 g of the HFA-ODA starter compound, 0.30 g of 3,3′-dihydroxybenzidine, 0.57 g of IPC, and 15 mL of DMAc were mixed for a period of 5 hours at room temperature in a N₂ atmosphere. The reaction liquid was combined with methanol, thereby precipitating a polymer. The polymer as precipitated was collected by filtration and then subjected to vacuum drying at a temperature of 50° C. The yield of the reaction was 87% by weight of the starter compound (1.23 g). Thereafter, the polymer was dissolved in a NMP solvent such that its concentration in the solvent was 0.5 g/dL. The intrinsic viscosity of the polymer solution at 25° C. as measured by an Ostwald viscometer was 0.45 dL/g. The results of NMR and IR spectroscopy indicated that a poly(benzoxazine-co-benzoxazole) precursor copolymer comprising the following repeating units had been formed:

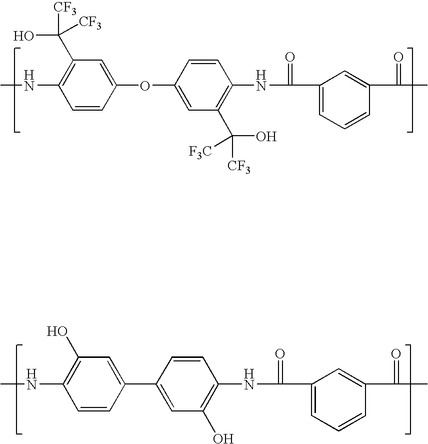

The foregoing precursor copolymer was partially cyclized by closing the benzoxazine rings made from the monomer shown above on the left converted to a PBOX/polybenzoxazole polymer by subjecting it to a thermal processing temperature of 260° C. for 0.5 hr. The precursor copolymer was then subjected to a thermal processing temperature of 320° C. for 0.5 hr. to close the benzoxazole rings made from the monomer shown above on the right.

### Example 3

In a three-neck flask having a volume of 300 mL, 0.75 g of the HFA-ODA starter compound, 0.30 g of 3,3′-dihydroxybenzidine, 1.21 g of 6FDC (shown above), and 9 mL of DMAc were mixed for a period of 5 hours at room temperature in a N₂ atmosphere. The reaction liquid was combined with methanol, thereby precipitating a polymer. The polymer as precipitated was collected by filtration and then subjected to vacuum drying at a temperature of 50° C. The yield of the reaction was 83% by weight of the starter compound (1.70 g). Then the polymer was dissolved in NMP solvent such that its concentration in the solvent was 0.5 g/dL. The intrinsic viscosity of the polymer solution at 25° C. as measured by an Ostwald viscometer was 0.56 dL/g. The results of NMR and IR spectroscopy indicated that a poly(benzoxazine-co-benzoxazole) precursor polymer comprising the following repeating units had been formed:

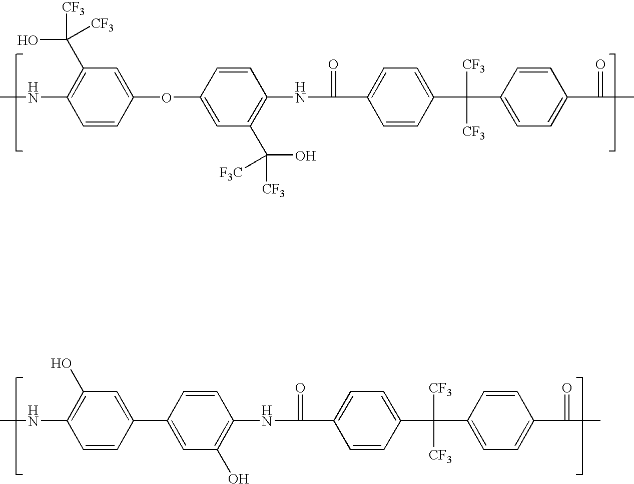

The foregoing precursor copolymer was partially cyclized by closing the benzoxazine rings made from the monomer shown above on the left converted to a PBOX/polybenzoxazole polymer by subjecting it to a thermal processing temperature of 260° C. for 0.5 hr. The precursor copolymer was then subjected to a thermal processing temperature of 320° C. for 0.5 hr. to close the benzoxazole rings made from the monomer shown above on the right.

### Example 4

In a three-neck flask having a volume of 300 μL, 1.50 g of the HFA-ODA starter compound, 0.66 g of 2,5-dihydroxyterephthaloyl chloride, and 10 mL of NMP were mixed for a period of 5 hours at room temperature in a N₂ atmosphere. The reaction liquid was combined with a mixture of methanol and water, thereby precipitating a polymer. The polymer as precipitated was collected by filtration and then subjected to vacuum drying at a temperature of 50° C. The yield of the reaction was 98% by weight of the starter compound (2.70 g). Then the polymer was dissolved in NMP solvent such that its concentration in the solvent was 0.5 g/dL. The intrinsic viscosity of the polymer solution at 25° C. as measured by an Ostwald viscometer was 0.13 dL/g. The results of NMR and IR spectroscopy indicated that a PBOX precursor polymer comprising the following repeating unit had been formed:

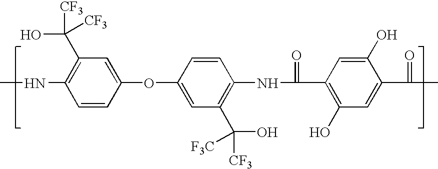

### Example 5

First, 3.95 g of the first PBOX precursor polymer shown in Table 1 and 6.0 g of DMF were mixed for a period of 12 hours at room temperature. Thus, the amount of polymer included in the solution was 40% by weight of the total solution. The resulting solution was applied to a glass substrate by means of spin coating at a rotation speed of 750 rpm for a period of 30 seconds. Next, the glass substrate was subjected to the following sequence of heat treatments: (1) 80° C. for a period of 30 minutes; (2) 150° C. for a period of 30 minutes, (3) 200° C. for a period of 30 minutes, (4) 250° C. for a period of 30 minutes, and (5) 300° C. for a period of 30 minutes. After cooling the glass substrate to room temperature, the glass substrate was placed in water for 24 hours, causing the film on the substrate to separate therefrom and float into the water. The freestanding film was then removed from the water and subjected to vacuum drying at a temperature of 100° C. The film had a thickness of 27 micrometers (μm). The result of IR spectroscopy showed that the film contained a polymer having the same structure as that of the PBOX polymer formed in Example 1. The result of thermogravimetric analysis showed that the film had a 5 weight (wt.) % thermal loss temperature of 468° C. and a 10 wt. % thermal loss temperature of 486° C. in a N₂ atmosphere. Thus, the PBOX-containing film exhibited high thermal stability.

### Example 6

A freestanding film was prepared in the same manner as the film described above in Example 5 except that 25 wt. % (based on the weight of the total solution) of the third PBOX precursor polymer shown in Table 1 of Example 1 was placed in the DMF solution. The film had a thickness of 67 μm. The result of thermal mechanical analysis showed that the film had a moderate glass transition temperature of 226° C. The result of IR spectroscopy indicated that the film contained a PBOX polymer comprising the following repeating unit:

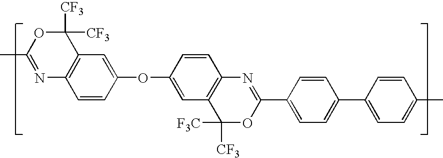

### Example 7

A freestanding film was prepared in the same manner as the film described above in Example 5 except that 25 wt. % (based on the weight of the total solution) of the fifth PBOX precursor polymer shown in Table 1 was placed in the DMF solution. The film had a thickness of 40 μm. The result of thermal mechanical analysis showed that this film also had a moderate glass transition temperature of 214° C. The result of IR spectra showed that the film contained a PBOX polymer comprising the following repeating unit:

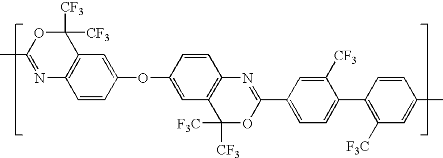

### Example 8

A freestanding film was prepared in the same manner as the film described above in Example 5 except that 25 wt. % (based on the weight of the total solution) of the fourth PBOX precursor polymer shown in Table 1 was placed in the DMF solution. The result of IR spectra showed that the film contained a PBOX polymer comprising the following repeating unit:

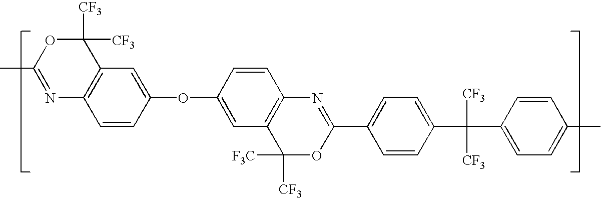

The water absorption of the PBOX polymer was determined to be 0.1% by weight of the polymer. The dielectric constant value of the PBOX polymer as measured at a frequency of 1 megaHertz (MHz) was determined to be 2.4.

### Example 9

Diazonaphthoquinone (DNQ) as represented by the following was provided:

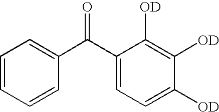

wherein D represents hydrogen or the sulfur-containing compound given below, with the molar ratio of H to sulfur-containing compound being approximately 34/66. This particular DNQ mixture is hereafter referred to “THBP” (which stands for trihydroxybenzophenone).

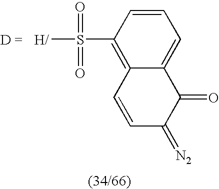

Within a vessel, 2 parts by weight of the THBP, 90 parts by weight of DMF, and 8 parts by weight of the PBOX polymer resin comprising the following repeating unit were mixed together:

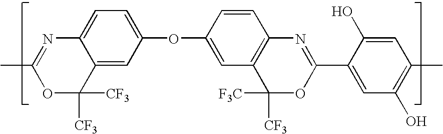

After homogeneously mixing these components, the resulting mixture was filtrated to prepare Sample A. Thus, the THBP was included at an amount of 2% by weight of the total mixture and at an amount of 20% by weight of the solids in the mixture.

Sample A was applied to a silicon substrate by means of spin coating at a rotation speed of 2,000 rpm for a period of 30 seconds. The silicon substrate was then heated at a temperature of 110° C. for a period of 5 minutes (soft bake). The film formed on the substrate had a thickness of 0.9 μm. Next, the surface of the film was covered by a mask plate having a pattern with size of line/space=150 μm/50 μm. Thereafter, the film was exposed to I-line radiation having a wavelength of 365 nm at a dose amount of 500 millijoules/squared centimeters (mJ/cm²). After the exposure, the film was developed in a TMAH aqueous solution having a concentration of 0.05 N. Then, the film was cured at a temperature of 300° C. for a period of 20 minutes (hard bake). The foregoing procedure of spin coating, soft baking, exposing, developing, and hard baking was repeated for samples B, F, and G.

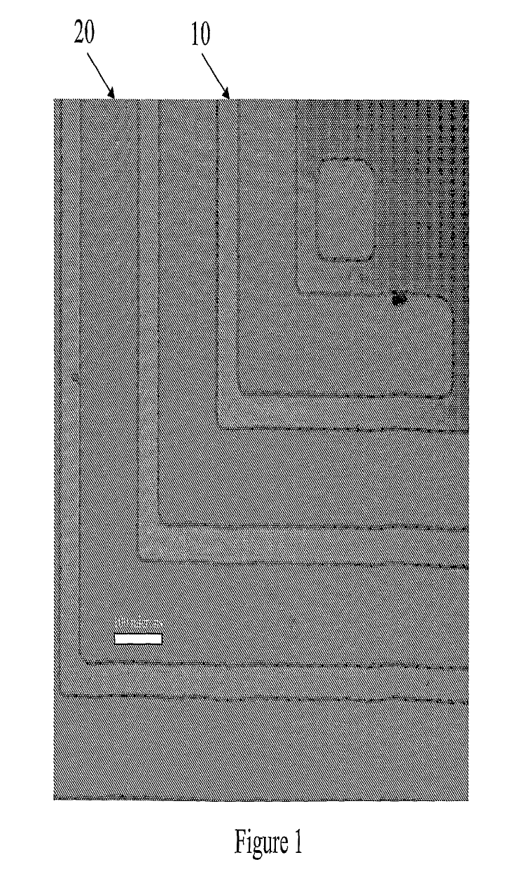

The relief pattern formed in the photosensitive PBOX film was then observed using an optical microscope. FIG. 1 shows the optical micrograph of the patterned PBOX film 10 upon a silicon substrate 20. The obtained relief pattern in film 10 corresponded closely to the pattern of the mask plate used. For example, the lines of the relief pattern in film 10 were spaced apart by 150 μm.

While preferred embodiments have been shown and described, modifications thereof can be made by one skilled in the art without departing from the spirit and teachings of those embodiments. The embodiments described herein are exemplary only and are not intended to be limiting. Many variations and modifications of the embodiments are possible and are within the scope thereof. Use of the term “optionally” with respect to any element of a claim is intended to mean that the subject element is required, or alternatively, is not required. Both alternatives are intended to be within the scope of the claim.

Accordingly, the scope of protection is not limited by the description set out above but is only limited by the claims which follow, that scope including all equivalents of the subject matter of the claims. Each and every claim is incorporated into the specification as an embodiment. Thus, the claims are a further description and are an addition to the preferred embodiments. The discussion of a reference herein is not an admission that it is prior art to the embodiments described herein, especially any reference that may have a publication date after the priority date of this application. The disclosures of all patents, patent applications, and publications cited herein are hereby incorporated by reference, to the extent that they provide exemplary, procedural, or other details supplementary to those set forth herein.

What is claimed is:

1. A photosensitive composition comprising:
(a) a polymer comprising a repeating unit represented by the following formula: 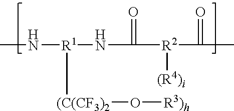
wherein R¹ comprises an aliphatic group, an alicyclic group, an aromatic group, a heterocyclic group, or combinations thereof,
wherein R² comprises an aliphatic group, an alicyclic group, an aromatic group, a heterocyclic group, or combinations thereof,
wherein R³ represents hydrogen or an organic group comprising a hydrophilic group, an acid-cleavable group, a base-cleavable group, a cross-linkable group, or combinations thereof,
wherein R⁴ comprises a hydrophilic group, a hydrophilic group protected by an acid-cleavable group, a hydrophilic group protected by a base-cleavable group, a cross-linkable group, or combinations thereof,
wherein h represents an integer of 1 or more, and
wherein i represents an integer of 0, 1, or more; and
(b) a photosensitive additive.

2. The photosensitive composition of claim 1, wherein the photosensitive additive comprises a photosensitive dissolution inhibitor, a photoacid generator, a photobase generator, a photo-free radical generator, or combinations thereof.

3. The photosensitive composition of claim 2, wherein the photosensitive dissolution inhibitor is present in the photosensitive composition in an amount in a range of from about 0.01% to about 40% by total weight of the polymer and the photosensitive additive.

4. The photosensitive composition of claim 2, wherein the photoacid generator is present in the photosensitive composition in an amount in a range of from about 0.01% to about 20% by total weight of the polymer and the photosensitive additive.

5. The photosensitive composition of claim 2, wherein the photobase generator is present in the photosensitive composition in an amount in a range of from about 0.01% to about 20% by total weight of the polymer and the photosensitive additive.

6. The photosensitive composition of claim 2, wherein the photo-free radical generator is present in the photosensitive composition in an amount in a range of from about 0.01% to about 20% by total weight of the polymer and the photosensitive additive.

7. The photosensitive composition of claim 1, further comprising a thermal acid generator, a cross-linker, a photosensitizer, or combinations thereof.

8. The photosensitive composition of claim 7, wherein the thermal acid generator is present in the photosensitive composition in an amount in a range of from about 0.01% to about 20% by total weight of the polymer and the photosensitive additive.

9. The photosensitive composition of claim 7, wherein the cross-linker is present in the photosensitive composition in an amount in a range of from about 0.01% to about 40% by total weight of the polymer and the photosensitive additive.

10. The photosensitive composition of claim 7, wherein the photosensitizer is present in the photosensitive composition in an amount in a range of from about 0.01% to about 20% by total weight of the polymer and the photosensitive additive.

11. The photosensitive composition of claim 1, wherein R³ is represented by the following formula: 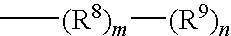
wherein R⁸ represents an organic group comprising from 1 to 40 carbon atoms,
wherein R⁹ comprises a hydrophilic group, a hydrophilic group protected by an acid-cleavable group, a hydrophilic group protected by a base-cleavable group, a cross-linkable group, or combinations thereof,
wherein m represents an integer of 0 or 1, and
wherein n represents an integer of 1 or more.

12. The photosensitive composition of claim 1, wherein R⁴ is represented by one of the following formulas: 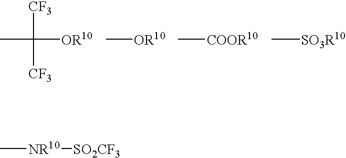
wherein R¹⁰ represents hydrogen or an organic group comprising an acid-cleavable group, a base-cleavable group, a cross-linkable group, or combinations thereof.

13. The photosensitive composition of claim 11, wherein R⁹ is represented by one of the following formulas: 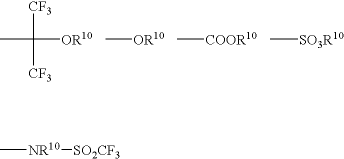
wherein R¹⁰ represents hydrogen or an organic group comprising an acid-cleavable group, a base-cleavable group, a cross-linkable group, or combinations thereof.

14. The photosensitive composition of claim 12, wherein R¹⁰ is represented by one of the following formulas: 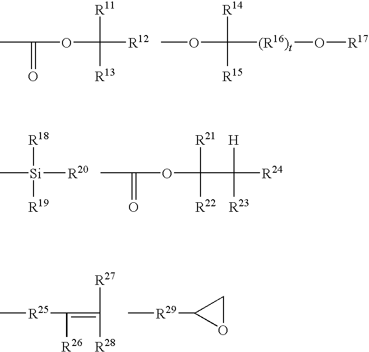
wherein R¹¹, R¹², and R¹³ each represents hydrogen or an organic group comprising from 1 to 40 carbon atoms,
wherein R¹⁴ and R¹⁵ each represents hydrogen or an organic group comprising from 1 to 40 carbon atoms,
wherein R¹⁶ and R¹⁷ each represents an organic group comprising from 1 to 40 carbon atoms,
wherein t represents an integer of 0 or 1,
wherein R¹⁵, R¹⁹, and R²⁰ each represents an organic group comprising from 1 to 40 carbon atoms,
wherein R²¹, R²², R²³, and R²⁴ each represents hydrogen or an organic group comprising from 1 to 40 carbon atoms,
wherein R²⁵ represents an organic group comprising from 1 to 40 carbon atoms,
wherein R²⁶, R²⁷, and R²⁸ each represents hydrogen or an organic group comprising from 1 to 40 carbon atoms, and
wherein R²⁹ represents an organic group comprising from 1 to 40 carbon atoms.

15. The photosensitive composition of claim 12, wherein R¹⁰ is represented by one of the following formulas: 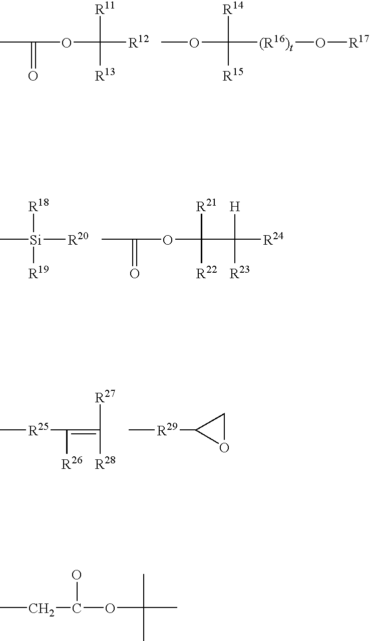
wherein R¹¹, R¹², and R¹³ each represents hydrogen or an organic group comprising from 1 to 40 carbon atoms,
wherein R¹⁴ and R¹⁵ each represents hydrogen or an organic group comprising from 1 to 40 carbon atoms,
wherein R¹⁶ and R¹⁷ each represents an organic group comprising from 1 to 40 carbon atoms,
wherein t represents an integer of 0 or 1,
wherein R¹⁸, R¹⁹, and R²⁰ each represents an organic group comprising from 1 to 40 carbon atoms,
wherein R²¹, R²², R²³, and R²⁴ each represents hydrogen or an organic group comprising from 1 to 40 carbon atoms,
wherein R²⁵ represents an organic group comprising from 1 to 40 carbon atoms,
wherein R²⁶, R²⁷, and R²⁸ each represents hydrogen or an organic group comprising from 1 to 40 carbon atoms, and
wherein R²⁹ represents an organic group comprising from 1 to 40 carbon atoms.

16. The photosensitive composition of claim 1, wherein
(i) R¹—(C(CF₃)₂—O—R³)ₕ is represented by the following formula: 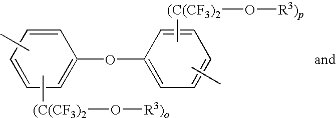
(ii) R²—(R⁴)ᵢ is represented by the following formula: 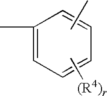
wherein p, o, and r each represents an integer of 0, 1, 2, 3, or 4, p+o>0, and
wherein R⁴ is represented by the following formula:
—OR¹⁰
wherein R¹⁰ represents hydrogen or an organic group comprising an acid-cleavable group, a base-cleavable group, a cross-linkable group, or combinations thereof.

17. The photosensitive composition of claim 1, wherein
(i) R¹—(C(CF₃)₂—O—R³)ₕ is represented by the following formula: 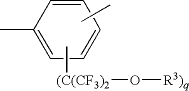
wherein q represents an integer of 1, 2, 3 or 4, and
(ii) R²—(R⁴)ᵢ is represented by the following formula: 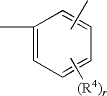
wherein r represents an integer of 0, 1, 2, 3 or 4, and
wherein R⁴ is represented by the following formula:
—OR¹⁰
wherein R¹⁰ represents hydrogen or an organic group comprising an acid-cleavable group, a base-cleavable group, a cross-linkable group, or combinations thereof.

18. The photosensitive composition of claim 1, wherein:
(i) R¹—(C(CF₃)₂—O—R³)ₕ is represented by the following formula: 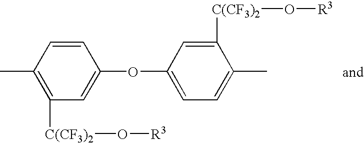
(ii) R³ represents hydrogen or an organic group represented by one of the following formulas:

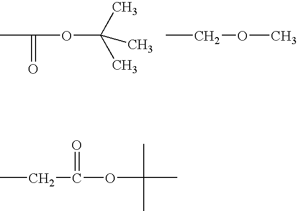

19. The photosensitive composition of claim 1, wherein R²—(R⁴)ᵢ is represented by one of the following formulas: 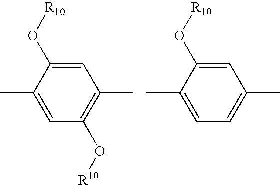
wherein R¹⁰ represents hydrogen or an organic group represented by one of the following formulas:

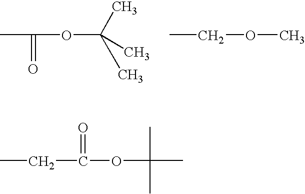

20. The photosensitive composition of claim 1, wherein the photosensitive composition is a positive tone or a negative tone photodefinable material.

21. The photosensitive composition of claim 1, further comprising an organic solvent.

22. The photosensitive composition of claim 21, wherein the organic solvent comprises an amide, an ether ester, a ketone, an ester, a glycol ether, a hydrocarbon, an aromatic hydrocarbon, a fluorinated solvent, a carbonate, or combinations thereof.

23. The photosensitive composition of claim 21, wherein the organic solvent comprises N,N-dimethyl formamide, gamma-butyrolactone, propylene glycol methyl ether, propylene glycol methyl ether acetate, tetrahydrofuran, 1-methyl-2-pyrrolidinone, N,N-dimethylacetamide, cyclohexanone, or combinations thereof.

24. The photosensitive composition of claim 1, wherein the composition becomes more or less soluble in an alkaline aqueous developing solution when exposed to actinic light.

25. The photosensitive composition of claim 1, wherein the composition becomes more or less soluble in an organic developing solution when exposed to actinic light.

26. The photosensitive composition of claim 1, having an absorbance in a range of from about 0.01 to about 0.5 μm⁻¹ for ultraviolet light having a wavelength of 365 nm.

27. A photosensitive composition comprising:
(a) a polymer comprising a repeating unit represented by the following formula: 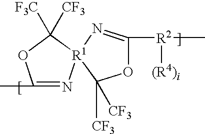
wherein R¹ comprises an aliphatic group, an alicyclic group, an aromatic group, a heterocyclic group, or combinations thereof,
wherein R² comprises an aliphatic group, an alicyclic group, an aromatic group, a heterocyclic group, or combinations thereof,
wherein R⁴ comprises a hydrophilic group, a hydrophilic group protected by an acid-cleavable group, a hydrophilic group protected by a base-cleavable group, a hydrophilic group protected by a cross-linkable group, or combinations thereof, and
wherein i represents an integer of 1 or more; and
(b) a photosensitive additive.

28. The photosensitive composition of claim 27, wherein the photosensitive additive comprises a photosensitive dissolution inhibitor, a photoacid generator, a photobase generator, a photo-free radical generator, or combinations thereof.

29. The photosensitive composition of claim 27, further comprising a photosensitive dissolution inhibitor, a thermal acid generator, a cross-linker, a photosensitizer, or combinations thereof.

30. The photosensitive composition of claim 27, wherein R⁴ is represented by one of the following formulas:
—OR¹⁰
—COOR¹⁰
—SO₃R¹⁰
—NR¹⁰—SO₂CF₃
wherein R¹⁰ represents hydrogen or an organic group comprising an acid-cleavable group, a base-cleavable group, a cross-linkable group, or combinations thereof.

31. The photosensitive composition of claim 30, wherein R¹⁰ is represented by one of the following formulas: 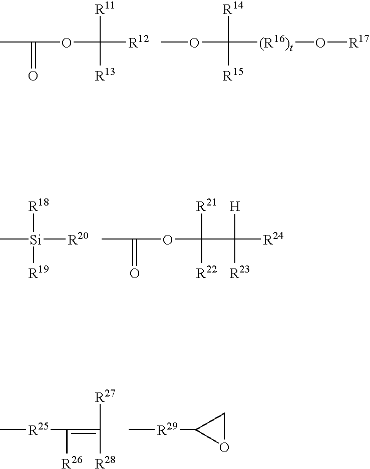
wherein R¹¹, R¹², and R¹³ each represents hydrogen or an organic group comprising from 1 to 40 carbon atoms,
wherein R¹⁴ and R¹⁵ each represents hydrogen or an organic group comprising from 1 to 40 carbon atoms,
wherein R¹⁶ and R¹⁷ each represents an organic group comprising from 1 to 40 carbon atoms,
wherein t represents an integer of 0 or 1,
wherein R¹⁸, R¹⁹, and R²⁰ each represents an organic group comprising from 1 to 40 carbon atoms,
wherein R²¹, R²², R²³, and R²⁴ each represents hydrogen or an organic group comprising from 1 to 40 carbon atoms,
wherein R²⁵ represents an organic group comprising from 1 to 40 carbon atoms,
wherein R²⁶, R²⁷, and R²⁸ each represents hydrogen or an organic group comprising from 1 to 40 carbon atoms, and
wherein R²⁹ represents an organic group comprising from 1 to 40 carbon atoms.

32. The photosensitive composition of claim 27, wherein
(i) R¹ is represented by the following formula: 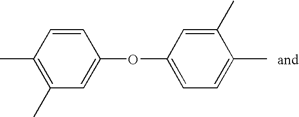
(ii) R²—(4)ᵢ is represented by the following formula: 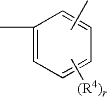
wherein r represents an integer of 1, 2, 3 or 4, and
wherein R⁴ is represented by the following formula:
—OR¹⁰
wherein R¹⁰ represents hydrogen or an organic group comprising an acid-cleavable group, a base-cleavable group, a cross-linkable group, or combinations thereof.

33. The photosensitive composition of claim 27, wherein
(i) R¹ is represented by the following formula: 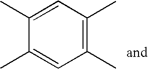
(ii) R²—(R⁴)ᵢ is represented by the following formula: 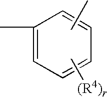
wherein r represents an integer of 1, 2, 3 or 4, and
wherein R⁴ is represented by the following formula:
—OR¹⁰
wherein R¹⁰ represents hydrogen or an organic group comprising an acid-cleavable group, a base-cleavable group, a cross-linkable group, or combinations thereof.

34. The photosensitive composition of claim 27, wherein R²—(R⁴)ᵢ is represented by one of the following formulas: 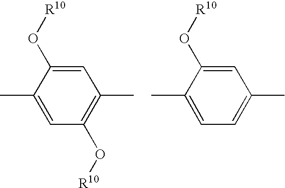
wherein R¹⁰ represents hydrogen or an organic group represented by one of the following formulas:

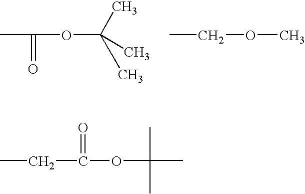

35. The photosensitive composition of claim 27, being made by a method comprising:
(a) forming a precursor polymer comprising a repeating unit represented by the following formula: 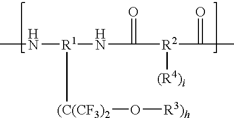
wherein R¹ comprises an aliphatic group, an alicyclic group, an aromatic group, a heterocyclic group, or combinations thereof,
wherein R² comprises an aliphatic group, an alicyclic group, an aromatic group, a heterocyclic group, or combinations thereof,
wherein R³ represents hydrogen or an organic group comprising a hydrophilic group, an acid-cleavable group, a base-cleavable group, a cross-linkable group, or combinations thereof,
wherein R⁴ comprises a hydrophilic group, a hydrophilic group protected by an acid-cleavable group, a hydrophilic group protected by a base-cleavable group, a hydrophilic group protected by a cross-linkable group, or combinations thereof,
wherein h represents an integer of 1 or more, and
wherein i represents an integer of 0, 1, or more; and
(b) combining the precursor polymer with the photosensitive additive and a solvent;
(c) patterning the precursor polymer using lithography; and
(d) heating the precursor polymer at a thermal processing temperature in a range of from about 180° C. to about 300° C. to convert the precursor polymer into the polymer.

36. The photosensitive composition of claim 27, being made from a precursor polymer by heating the precursor polymer at a thermal processing temperature in a range of from about 180° C. to about 300° C.

37. The photosensitive composition of claim 27, being made from a precursor polymer by heating the precursor polymer at a thermal processing temperature in a range of from about 200° C. to about 260° C.

38. The photosensitive composition of claim 27, wherein the photosensitive composition is a positive tone or a negative tone photodefinable material.

39. The photosensitive composition of claim 27, further comprising an organic solvent.

40. The photosensitive composition of claim 39, wherein the organic solvent comprises an amide, an ether ester, a ketone, an ester, a glycol ether, a hydrocarbon, an aromatic hydrocarbon, a fluorinated solvent, carbonate, or combinations thereof.

41. The photosensitive composition of claim 39, wherein the organic solvent comprises N,N-dimethyl formamide, gamma-butyrolactone, propylene glycol methyl ether acetate, tetrahydrofuran, 1-methyl-2-pyrrolidinone, N,N-dimethylacetamide, cyclohexanone, or combinations thereof.

42. The photosensitive composition of claim 27, wherein the polymer exhibits a dielectric constant in a range of from about 2.0 to about 3.0.

43. The photosensitive composition of claim 27, wherein the polymer exhibits a water absorption in a range of from about 0.01% to about 3% by weight of the polymer.

44. A photosensitive composition comprising:
(a) a polybenzoxazole copolymerized with a polybenzoxazine; and
(b) a photosensitive additive.

45. The photosensitive composition of claim 44, wherein the polybenzoxazine comprises a repeating unit represented by the following formula: 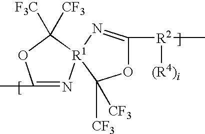
wherein R¹ comprises an aliphatic group, an alicyclic group, an aromatic group, a heterocyclic group, or combinations thereof,
wherein R² comprises an aliphatic group, an alicyclic group, an aromatic group, a heterocyclic group, or combinations thereof,
wherein R⁴ comprises a hydrophilic group, a hydrophilic group protected by an acid-cleavable group, a hydrophilic group protected by a base-cleavable group, a hydrophilic group protected by a cross-linkable group, or combinations thereof, and
wherein i represents an integer of 1 or more.

46. The photosensitive composition of claim 44, wherein the photosensitive additive comprises a diazonium salt, a diazoquinone sulphonamide, a diazoquinone sulphonic acid ester, a diazoquinone sulphonate, a nitrobenzyl ester, an onium salt, a halide, a halogenated isocyanate, a triazine halide, a bisarylsulphonyldiazomethane, a disulphone, an o-diazoquinone, a photoacid generator, a photobase generator, a photo-free radical generator, or combinations thereof.

47. A polymeric composition comprising a repeating unit represented by the following formula:

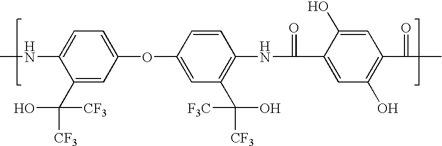

48. A polymeric composition comprising a repeating unit represented by the following formula:

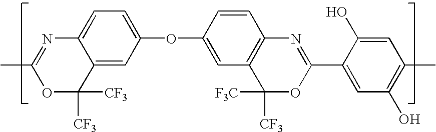

49. A polymeric composition comprising a repeating unit represented by the following formula:

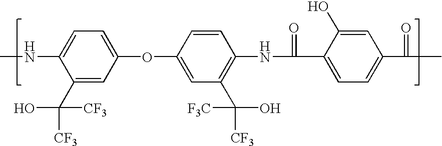

50. A polymeric composition comprising a repeating unit represented by the following formula: [chemical structure]
